(19) United States
(12) Patent Application Publication
(10) Pub. No.: US 2024/0331768 A1
(43) Pub. Date: Oct. 3, 2024

(54) BITCELL PROCESS COMPENSATED READ ASSIST SCHEME FOR SRAM

(71) Applicant: STMicroelectronics International N.V., Geneva (CH)

(72) Inventors: Praveen Kumar VERMA, Greater Noida (IN); Ashfaque AHMED, Narkatiaganj (IN)

(73) Assignee: STMicroelectronics International N.V., Geneva (CH)

(21) Appl. No.: 18/619,699

(22) Filed: Mar. 28, 2024

Related U.S. Application Data
(60) Provisional application No. 63/456,071, filed on Mar. 31, 2023.

(51) Int. Cl. G11C 11/419; G11C 11/418

(52) U.S. Cl. CPC G11C 11/419; G11C 11/418

(57) ABSTRACT

An electronic device includes a memory and includes a plurality of word lines selectively driven by a decoder, with each pair of adjacent word lines having an underdrive circuit coupled therebetween. That underdrive circuit includes first and second transistors source/drain coupled in series with one another between the pair of adjacent word lines, the first and second transistors being replicas of a pull-down transistor and a pass gate transistor of bitcells the memory. One of the first and second transistors has its gate driven by a supply voltage and the other of the first and second transistor has its gate driven by a first read assist control signal.

### RELATED APPLICATION

This application claims priority to U.S. Provisional Application for Patent No. 63/456,071, filed Mar. 31, 2023, the contents of which are incorporated by reference in their entirety.

### TECHNICAL FIELD

This disclosure pertains to the domain of static random-access memory (SRAM), specifically focusing on an SRAM architecture that employs a process and temperature-compensated word line underdrive scheme. This approach enables low voltage applications while maintaining high bitcell stability.

### BACKGROUND

Static random access memory (SRAM) is widely utilized in modern electronic devices. The read and write speed of SRAM is of particular interest in many applications since inadequate performance can degrade the overall performance of the integrated electronic device. In mobile device applications such as smartphones, tablets, laptops, smartwatches, and other wearables, it is desired to maintain low power consumption and compactness to optimize battery life and fit within the given housing size.

Reference is made to FIG. 1, which shows a simplified block diagram of a memory circuit 10, including an array 12 of memory cells C arranged in m rows and n columns. The memory cells in each row are controlled by a word line from among word lines 14a, . . . , 14m. The memory cells in each column are connected to a bit line from among bit lines 16a, . . . , 16n. A row decoder circuit 18 receives a row address that is predecoded from an address 20 and decodes the bits of the row address to select and actuate one of the word lines 14a, . . . , 14m. A column decoder circuit 22 receives a column address that is predecoded from the address 20 and decodes the bits of the column address to select a plurality of the bit lines 16a, . . . , 16n. In write mode, data on the data input/output lines 24 is written to the memory cells which are located at the intersections of the selected one of the word lines 14a, . . . , 14m and the plurality of bit lines 16a, . . . , 16n selected by the address 20. In read mode, data stored in the memory cells which are located at the intersections of the selected one of the word lines 14a, . . . , 14m and the plurality of bit lines 16a, . . . , 16n selected by the address 20 is read out to the data input/output lines 24.

A successful read or write operation is contingent on application of the actuation voltage (typically a supply voltage Vdd) by the word line driver circuit at the selected one of the word lines 14a, . . . , 14m to each memory cell C in the selected row. However, in memory devices manufactured with smaller transistors, using the supply voltage to power the word lines can lead to degraded static noise margins (SNM) within the memory cells due to physical properties of the smaller transistors and manufacturing variation.

SNM is a characteristic that quantifies an amount of electric noise that a memory cell can withstand without compromising the integrity of a stored logic value. As memory cells are manufactured with smaller transistors, SNM tends to become smaller, increasing the likelihood of erroneous switching of stored logic values and resulting in data errors.

A typical memory cell is comprised of a pair of cross coupled inverters each selectively connected to a respective bit line or complementary bit line by a pass gate transistor activated by the word line. The SNM of a memory cell is a function of a strength of a pass gate of the memory cell versus a strength of a pull-down gate (e.g., NMOS components) of the memory cell.

For example, a logic value of “0” may be represented in a memory cell as a stored voltage of 0 mV. Noise associated with the memory cell when a respective word line is activated may cause the stored voltage to actually be 150 mV. The stored value of 150 mV from the electric noise may be caused by crosstalk, electromagnetic interference, electrostatic interference, thermal noise, and so on. However, the stored voltage is still interpreted as a logic value of “0” because 150 mV is within the SNM of the memory cell. Thus, the memory cell can be said to have a SNM of at least 150 mV.

However, as memory cells are manufactured with smaller transistors, SNM also tends to become smaller. Accordingly, a memory cell manufactured with smaller transistors may have a SNM of 100 mV. Thus, when a source voltage (Vdd) is applied to the word line, noise associated with activating the word line can exceed the SNM of the memory cell. Consequently, a stored logic value may be erroneously switched when the source voltage is applied to the word line because of the degraded SNM.

By weakening the strength of the pass gate, i.e., reducing a voltage used to activate the word line, the SNM increases because the ratio of the strengths of the pass gate and pull down gate decreases. An increased SNM permits the memory cell to handle additional noise which causes the memory cell to be less likely to erroneously flip between stored logic values resulting in data errors, thereby enhancing stability of the bit cells (e.g., cross coupled inverters) within the memory cells.

Difficulty arises in that the amount of word line underdrive that achieves stability changes depending upon process corner and temperature.

One known way to achieve this is to use an underdrive transistor (also referred to as a pull-down or bleeder transistor) connected to the word line to act as a voltage divider with the PMOS transistor of the word line driver circuit, with the sizing of the underdrive transistor being set so as to achieve stability at the FS (fast N, slow P) process corner (the worst corner) and high temperature. While this achieves stability, this underdrive level is in excess at the SF and SS corners (as well as low temperature), reducing speed. In addition, where the word line driver is a PMOS transistor and the underdrive transistor is an NMOS transistor, the PMOS word line driver and the NMOS word line underdrive transistor vary differently, adding further mismatch between the underdrive levels used (and underdrive levels that could otherwise be used) at certain corners and temperatures.

An improvement on this is to drive the gate of the NMOS transistor connected to the word line as a voltage divider with a temperature and process compensated gate voltage. While this does reduce drawbacks with using the NMOS transistor as the underdrive transistor, the mismatch resulting from the word line driver being a PMOS transistor while the word line underdrive transistor is that an NMOS transistor is still present. Moreover, the use of logic devices in the generation of the compensated gate voltage introduces its own mismatches between the transistors forming the bit cells within the memory cells and the transistors forming the logic devices.

Instead of using an NMOS transistor connected the word line as a voltage divider, a PMOS transistor may instead be connected to the word line as a voltage divider to cause underdrive of the word line. Utilizing a PMOS transistor does reduce mismatch because both the world line driver and word line underdrive transistor are PMOS transistors. However, since the sizing of the PMOS transistor is still based upon the FS corner, the resulting underdrive level is still in excess at the SF and SS corners (as well as low temperature), reducing potential speed.

An improvement lies in driving the gate of the PMOS transistor connected to the word line as a voltage divider with a temperature and process compensated gate voltage. While this does reduce drawbacks, the size of the PMOS transistor itself (since PMOS devices are physically larger than NMOS devices) puts a constraint on its usage as a word line underdrive transistor.

In summary, the limitations of the prior art described above are: the use of a single NMOS transistor as an underdrive transistor saves space as compared to a PMOS transistor but speed optimization suffers; the use of an NMOS transistor with a temperature and process controlled gate voltage may involve greater area usage, but the underdrive level may move differently than the bit cells of the memory cells over process and temperature variation; and the use of a PMOS transistor with a temperature and process controlled gate voltage may involve even greater area usage than when compensating an NMOS transistor and the underdrive level may move differently than the bit cells of the memory cells over process and temperature variation.

There is therefore still a need for further development.

### SUMMARY

An electronic device features a memory and includes a multitude of word lines that are selectively driven by a decoder. Each pair of adjacent word lines is connected by an underdrive circuit, which incorporates first and second transistors source/drain coupled in series between the pair of adjacent word lines. These first and second transistors are replicas of a pull-down transistor and a pass gate transistor found in bitcells of the memory. One of the first and second transistors has its gate driven by a supply voltage, while the other has its gate driven by a first read assist control signal.

Each word line may also include a first bleeder transistor source/drain connected between the word line and ground, with the gate of the first bleeder transistor driven by a second read assist control signal.

The second read assist control signal may be adjusted to account for process, voltage, and temperature variance.

Each word line may additionally feature a second bleeder transistor source/drain connected between the word line and ground. The gate of the second bleeder transistor may be driven by a third read assist control signal. Notably, the second bleeder transistor may be a PMOS transistor, while the first bleeder transistor may be an NMOS transistor.

Each word line may also include a pull-up compensation transistor source-drain connected between the supply voltage and the word line. The gate of the pull-up compensation transistor may be driven by an inverse of the first read assist control signal.

Each word line may additionally feature a first bleeder transistor source/drain connected between the word line and ground, with the gate of the first bleeder transistor driven by a second read assist control signal.

An electronic device features a memory and includes a multitude of word lines that are selectively driven by a decoder. Each word line is connected to an underdrive circuit, which includes a first transistor coupled to the word line. This transistor is a replica of a pull-down transistor or a pass gate transistor found in bitcells of the memory. Additionally, each word line has a first bleeder transistor source/drain coupled between the word line and ground, with its gate driven by a first read assist control signal.

The first transistor may be source/drain coupled between the word line and ground, with its gate driven by a supply voltage. Alternatively, the first transistor may be source/drain coupled between the word line and ground, with its gate driven by a second read assist control signal.

For each word line, the first transistor may be coupled between that word line and an immediately adjacent word line. The first transistor for each word line could have its gate driven by a supply voltage or a second read assist control signal.

The first read assist control signal may be adjusted to account for process, voltage, and temperature variance. The first bleeder transistor may be an NMOS transistor.

In some embodiments, each word line may include a second bleeder transistor source/drain coupled between the word line and ground, with its gate driven by a third read assist control signal. Notably, the first bleeder transistor may be an NMOS transistor, while the second bleeder transistor may be a PMOS transistor.

An electronic device features a memory and includes decoder logic and word line driver circuitry for each given row within the memory. The decoder logic generates an initial word line signal, while the word line driver circuitry generates a word line drive signal at an intermediate node from the initial word line signal and a word line signal at a word line node for that given row from the word line drive signal. The device also has a first adjacent word line node associated with a first row immediately adjacent to the given row.

The device includes a first replica transistor with a first conduction terminal connected to the first adjacent word line node and a control terminal coupled to a first control signal. Additionally, the device has a second replica transistor with a first conduction terminal connected to a second conduction terminal of the first replica transistor, a second conduction terminal connected to the word line node, and a control terminal coupled to a supply voltage. The first replica transistor is a replica of pass gate transistors of bitcells in the given row within the memory, and the second replica transistor is a replica of certain transistors of bitcells in the given row within the memory.

In some embodiments, the first and second replica transistors are NMOS transistors. The second replica transistor may be a replica of NMOS transistors of the memory cells of the given row within the memory.

The device may further include a third replica transistor with a first conduction terminal connected to the word line node and a gate coupled to the supply voltage, and a fourth replica transistor with a first conduction terminal connected to a second conduction terminal of the third replica transistor, a second conduction terminal coupled to a second adjacent word line node, and a gate coupled to the first control signal. The second adjacent word line node is associated with a second row immediately adjacent to the given row. The third replica transistor is a replica of certain transistors of memory cells associated with the second adjacent word line node, and the fourth replica transistor is a replica of pass gate transistors of the memory cells associated with the second adjacent word line node.

For each given row within the memory, the device may include a first bleeder transistor with a first conduction terminal connected to the word line node, a second conduction terminal connected to ground, and a control terminal coupled to a second control signal. The second control signal may be adjusted to account for process, voltage, and temperature variation. The first bleeder transistor may be either a PMOS or an NMOS transistor.

In some embodiments, the device may also include a second bleeder transistor with a source connected to the word line node, a source connected to ground, and a gate coupled to the second control signal.

The first control signal may be analog and set the conductivity of the first replica transistor, or it may be digital and turn the first replica transistor on or off.

An electronic device features a memory and includes decoder logic and word line driver circuitry for each given row within the memory. The decoder logic generates a word line drive signal, while the word line driver circuitry generates a word line signal at a word line node for that given row from the word line drive signal. The device also has a replica transistor with a first conduction terminal coupled to the word line node and a control terminal. The replica transistor is a replica of certain transistors of memory cells (i.e., bitcells) of the given row within the memory.

In some embodiments, the control terminal of the replica transistor is coupled to a control signal that is adjusted to account for process, voltage, and temperature variation. Alternatively, the control terminal of the replica transistor may be coupled to a supply voltage.

The replica transistor may have a second conduction terminal coupled to a first adjacent word line node, which is associated with a first row immediately adjacent to the given row. In other embodiments, the replica transistor may have a second conduction terminal coupled to ground.

The replica transistor may be a replica NMOS transistor with its drain connected to the word line node, being a replica of NMOS transistors within the given row within the memory.

### BRIEF DESCRIPTION OF THE DRAWINGS

FIG. 1 is a block diagram showing a prior art SRAM device.

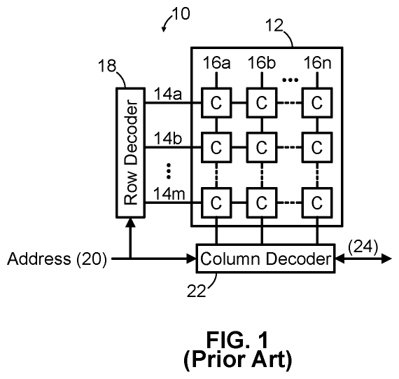

FIG. 2 is a schematic block diagram showing a first embodiment of a memory device and word line underdrive circuitry disclosed herein.

FIG. 3 is a schematic block diagram showing a second embodiment of a memory device and word line underdrive circuitry disclosed herein.

FIG. 4 is a schematic block diagram showing a third embodiment of a memory device and word line underdrive circuitry disclosed herein.

FIG. 5 is a schematic block diagram showing a fourth embodiment of a memory device and word line underdrive circuitry disclosed herein.

FIG. 6 is a schematic block diagram showing a fifth embodiment of a memory device and word line underdrive circuitry disclosed herein.

FIG. 7 is a schematic block diagram showing a sixth embodiment of a memory device and word line underdrive circuitry disclosed herein.

FIG. 8 is a schematic block diagram showing a seventh embodiment of a memory device and word line underdrive circuitry disclosed herein.

FIG. 9 is a schematic block diagram showing an eighth embodiment of a memory device and word line underdrive circuitry disclosed herein.

FIG. 10 is a schematic block diagram showing a ninth embodiment of a memory device and word line underdrive circuitry disclosed herein.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

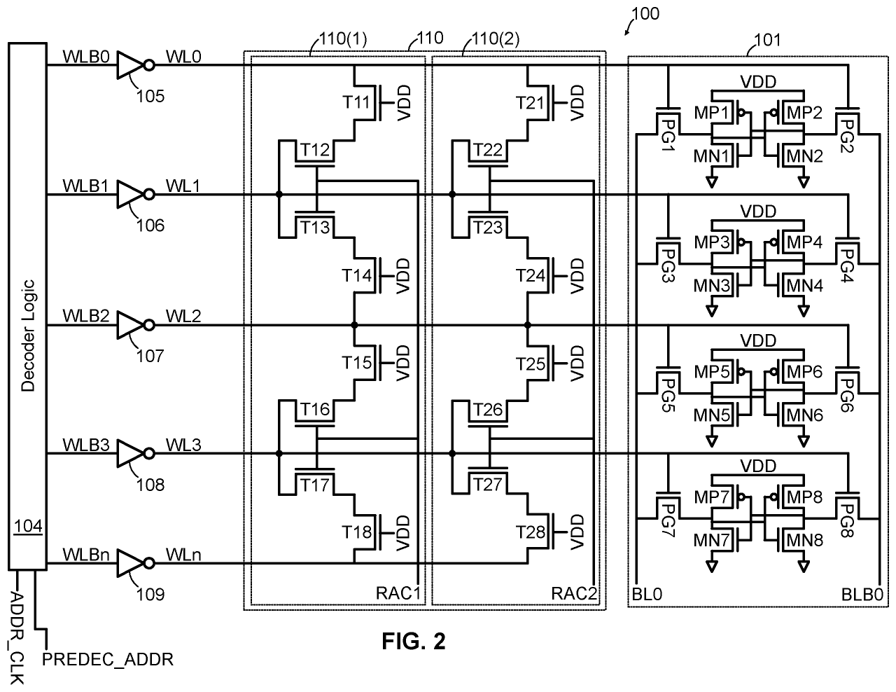

Now described with reference to FIG. 2 is an SRAM architecture 100 comprised of an m-by-n SRAM memory 101 (having m columns and n rows), row decoders 104, column decoders (not shown), a pre-decoder (not shown), word line drivers 105-109 and word line underdrive circuitry 110. The number of row decoders and the number of rows in the SRAM 101 are equal, and each row decoder is paired to one row of the SRAM 101.

In the example shown there is one column (m=1) and five rows (n=5), these numbers being chosen for ease of illustration and explanation, but it should be understood there may be any number of columns and rows, for example 32 columns (m=32) and 1024 rows (n=1024).

The memory cell corresponding to the first row (row0) includes a pair of cross coupled inverters formed by PMOS MP1/NMOS MN1 and PMOS MP2/NMOS MN2, with pass gate NMOS transistors PG1 and PG2 providing read and write access to the memory cell. In greater detail, the first inverter is formed by: PMOS MP1 having its source connected to supply voltage VDD, its drain connected to the drain of NMOS MN1, and its gate connected to the source of pass gate NMOS PG2; and NMOS MN1 having its drain connected to the drain of PMOS MP1, its source connected to ground, and its gate connected to the gate of PMOS MP1 and the source of pass gate NMOS PG2. The second inverter is formed by: PMOS MP2 having its source connected to supply voltage VDD, its drain connected to the drain of NMOS MN2, and its gate connected to the source of pass gate NMOS PG1; and NMOS MN2 having its drain connected to the drain of PMOS MP2, its source connected to ground, and its gate connected to the gate of PMOS MP2 and the source of pass gate NMOS PG1. Pass gate NMOS transistor PG1 has its drain connected to bit line BLO, its source connected to the drains of MP1 and MN1, and its gate connected to word line WLO. Pass gate NMOS transistor PG2 has its drain connected to complementary bit line BLBO, its source connected to the drains of MP2 and MN2, and its gate connected to word line WLO.

The memory cell corresponding to the second row (row1) includes a pair of cross coupled inverters formed by PMOS MP3/NMOS MN3 and PMOS MP4/NMOS MN4, with pass gate NMOS transistors PG3 and PG4 providing read and write access to the memory cell. In greater detail, the first inverter is formed by: PMOS MP3 having its source connected to supply voltage VDD, its drain connected to the drain of NMOS MN3, and its gate connected to the source of pass gate NMOS PG4; and NMOS MN3 having its drain connected to the drain of PMOS MP3, its source connected to ground, and its gate connected to the gate of PMOS MP3 and the source of pass gate NMOS PG4. The second inverter is formed by: PMOS MP4 having its source connected to supply voltage VDD, its drain connected to the drain of NMOS MN4, and its gate connected to the source of pass gate NMOS PG3; and NMOS MN4 having its drain connected to the drain of PMOS MP4, its source connected to ground, and its gate connected to the gate of PMOS MP4 and the source of pass gate NMOS PG3. Pass gate NMOS transistor PG3 has its drain connected to bit line BLO, its source connected to the drains of MP3 and MN3, and its gate connected to word line WL1. Pass gate NMOS transistor PG4 has its drain connected to complementary bit line BLBO, its source connected to the drains of MP4 and MN4, and its gate connected to word line WL1.

The memory cell corresponding to the third row (row2) includes a pair of cross coupled inverters formed by PMOS MP5/NMOS MN5 and PMOS MP6/NMOS MN6, with pass gate NMOS transistors PG5 and PG6 providing read and write access to the memory cell. In greater detail, the first inverter is formed by: PMOS MP5 having its source connected to supply voltage VDD, its drain connected to the drain of NMOS MN5, and its gate connected to the source of pass gate NMOS PG6; and NMOS MN5 having its drain connected to the drain of PMOS MP5, its source connected to ground, and its gate connected to the gate of PMOS MP5 and the source of pass gate NMOS PG6. The second inverter is formed by: PMOS MP6 having its source connected to supply voltage VDD, its drain connected to the drain of NMOS MN6, and its gate connected to the source of pass gate NMOS PG5; and NMOS MN6 having its drain connected to the drain of PMOS MP6, its source connected to ground, and its gate connected to the gate of PMOS MP6 and the source of pass gate NMOS PG5. Pass gate NMOS transistor PG5 has its drain connected to bit line BLO, its source connected to the drains of MP5 and MN5, and its gate connected to word line WL2. Pass gate NMOS transistor PG6 has its drain connected to complementary bit line BLBO, its source connected to the drains of MP6 and MN6, and its gate connected to word line WL2.

The memory cell corresponding to the fourth row (row3) includes a pair of cross coupled inverters formed by PMOS MP7/NMOS MN7 and PMOS MP8/NMOS MN8, with pass gate NMOS transistors PG7 and PG8 providing read and write access to the memory cell. In greater detail, the first inverter is formed by: PMOS MP7 having its source connected to supply voltage VDD, its drain connected to the drain of NMOS MN7, and its gate connected to the source of pass gate NMOS PG8; and NMOS MN7 having its drain connected to the drain of PMOS MP7, its source connected to ground, and its gate connected to the gate of PMOS MP7 and the source of pass gate NMOS PG8. The second inverter is formed by: PMOS MP8 having its source connected to supply voltage VDD, its drain connected to the drain of NMOS MN8, and its gate connected to the source of pass gate NMOS PG7; and NMOS MN8 having its drain connected to the drain of PMOS MP8, its source connected to ground, and its gate connected to the gate of PMOS MP8 and the source of pass gate NMOS PG7. Pass gate NMOS transistor PG7 has its drain connected to bit line BLO, its source connected to the drains of MP7 and MN7, and its gate connected to word line WL3. Pass gate NMOS transistor PG8 has its drain connected to complementary bit line BLBO, its source connected to the drains of MP8 and MN8, and its gate connected to word line WL3.

The memory cell corresponding to the fifth row (row4) and word line WLn is not shown for brevity.

The pre-decoder (not shown) receives an address, pre-decodes the address, and sends the pre-decoded address PREDEC_ADDR to decoder logic 104. From the pre-decoded address PREDEC_ADDR, the decoder logic 104 generates the word line signals WLB0, . . . , WLBn on the corresponding word lines having those labels. Word line drivers (e.g., inverters 105-109) receive the word line signals WLB0, . . . , WLBn at their inputs, and output corresponding word line signals WL0, . . . , WLn.

Underdrive circuitry 110 is connected to the word lines WL0, . . . , WLBn and functions to provide a selectable process, voltage, and temperature compensated amount of underdrive to the word lines WLB0, . . . , WLBn as they are activated. First, the circuit layout of the underdrive circuitry 110 will be described and then the function of the underdrive circuitry 110 during operation will be explained.

The underdrive circuitry 110 includes one or more tracking columns. In the illustrated example, there are two tracking columns 110(1) and 110(2), with it being understood there may be any number of such tracking columns. Each tracking column 110(1) and 110(2) includes, for each word line, a transistor which is a replica of the pass gates of the memory cell (bitcell) associated with that word line and a transistor which is replica of the NMOS (pull down) transistors of the latch circuit (in the bitcell) associated with that word line.

In greater detail, the tracking column 110(1) includes, for word line WLO: NMOS transistor T11 (a replica of NMOS transistors MN1/MN2) having its drain connected to word line WLO, its source connected to the source of transistor T12 at an intermediate node, and its gate connected to VDD; NMOS transistor T12 (a replica of NMOS transistors PG1/PG2) having its drain connected to the source of transistor T11 at the intermediate node, its source connected to word line WL1, and its gate connected to receive a read assist control signal RAC1. Here, in terms of transistor layout/formation, the source of transistor T11 and the drain of transistor T12 at the intermediate node may be formed a single shared source/drain region.

The tracking column 110(1) further includes, for word line WL1: NMOS transistor T13 (a replica of NMOS transistors PG3/PG4) having its drain connected to the word line WL1, its source connected to the drain of NMOS transistor T14 at an intermediate node, and its gate connected to the read assist control signal RAC1; and NMOS transistor T14 (a replica of NMOS transistors MN3/MN4) having its drain connected to the source of NMOS transistor T13 at the intermediate node, its source connected to word line WL2, and its gate connected to VDD. The source of transistor T13 and the drain of transistor T14 at the intermediate node may be formed as a single shared source/drain region.

The tracking column 110(1) includes, for word line WL2: NMOS transistor T15 (a replica of NMOS transistors MN5/MN6) having its drain connected to word line WL2, its source connected to the source of NMOS transistor T16 at an intermediate node, and its gate connected to VDD; NMOS transistor T16 (a replica of NMOS transistors PG5/PG6) having its drain connected to the source of NMOS transistor T15 at the intermediate node, its source connected to word line WL3, and its gate connected to read assist control signal RAC1. The source of transistor T15 and the drain of transistor T16 at the intermediate node may be formed as a single shared source/drain region.

The tracking column 110(1) includes, for word line WLA: NMOS transistor T17 (a replica of NMOS transistors PG7/PG8) having its drain connected to the word line WL3, its source connected to the drain of NMOS transistor T18 at an intermediate node, and its gate connected to the read assist control signal RAC1; and NMOS transistor T18 (a replica of NMOS transistors MN7/MN8) having its drain connected to the source of NMOS transistor T1 at the intermediate node, its source connected to word line WLn, and its gate connected to VDD. The source of transistor T17 and the drain of transistor T18 at the intermediate node may be formed as a single shared source/drain region.

The tracking column 110(2) includes, for word line WLO: NMOS transistor T21 (a replica of NMOS transistors MN1/MN2) having its drain connected to word line WLO, its source connected to the source of NMOS transistor T22 at an intermediate node, and its gate connected to VDD; NMOS transistor T22 (a replica of NMOS transistors PG1/PG2) having its drain connected to the source of NMOS transistor T21 at the intermediate node, its source connected to word line WL1, and its gate connected to read assist control signal RAC2. The source of transistor T21 and the drain of transistor T22 at the intermediate node may be formed in a single shared source/drain region.

The tracking column 110(2) includes, for word line WL1: NMOS transistor T23 (a replica of NMOS transistors PG3/PG4) having its drain connected to the word line WL1, its source connected to the drain of NMOS transistor T24 at an intermediate node, and its gate connected to the read assist control signal RAC2; and NMOS transistor T24 (a replica of NMOS transistors MN3/MN4) having its drain connected to the source of NMOS transistor T23 at the intermediate node, its source connected to word line WL2, and its gate connected to VDD. The source of transistor T23 and the drain of transistor T24 at the intermediate node may be formed in a single shared source/drain region.

The tracking column 110(2) includes, for word line WL2: NMOS transistor T25 (a replica of NMOS transistors MN5/MN6) having its drain connected to word line WL2, its source connected to the source of NMOS transistor T26 at an intermediate node, and its gate connected to VDD; NMOS transistor T26 (a replica of NMOS transistors PG5/PG6) having its drain connected to the source of NMOS transistor T25 at the intermediate node, its source connected to word line WL3, and its gate connected to read assist control signal RAC2. The source of transistor T25 and the drain of transistor T26 at the intermediate node may be formed in a single shared source/drain region.

The tracking column 110(2) includes, for word line WLA: NMOS transistor T27 (a replica of NMOS transistors PG7/PG8) having its drain connected to the word line WL3, its source connected to the drain of NMOS transistor T28 at an intermediate node, and its gate connected to the read assist control signal RAC2; and NMOS transistor T28 (a replica of NMOS transistors MN7/MN8) having its drain connected to the source of NMOS transistor T27 at the intermediate node, its source connected to word line WLn, and its gate connected to VDD. The source of transistor T27 and the drain of transistor T28 at the intermediate node may be formed in a single shared source/drain region.

Operation in read mode is now described. As stated, the pre-decoder (not shown) receives an address, pre-decodes the address, and sends the pre-decoded address PREDEC_ADDR to decoder logic 104. From the pre-decoded address PREDEC_ADDR, the decoder logic 104 generates the word line signals WLB0, . . . , WLBn on the corresponding word lines having those labels (with one word line signal being asserted during a read and the other word line signals being deasserted during the read). Inverters 105-109 receive the word line signals WLB0, . . . , WLBn at their inputs, and output corresponding word line signals WLO, . . . , WLn.

One word line at a time is asserted to a logic high, with the other word lines being deasserted to a logic low. Consider now the case where address indicates selection of row3.

Therefore, the decoder logic 104 pulls WLB2 low while driving WLB0, WLB1, WLB3, and WLBn high, with the result being that the word line WL2 is asserted while the word lines WLO, WL1, WL3, and WLn are deasserted (coupled to ground). Since transistors T14, T15 and T24, T25 have their gates coupled to the supply voltage VDD, this means that WL2 is coupled to ground through transistors T13, T16 and T23, T26. The conductivity of transistors T13, T16 and T23, T26 is set by the read assist control signals RAC1 and RAC2, and since transistors T13, T16, and T23, T26 are on, the amount of underdriving of the word line WL2 (by sinking current from WL2 to ground) is set by the read assist control signals RAC1 and RAC2. The values for the read assist control signals RAC1 and RAC2 may be provided from an external source via a pin or may be provided by the device into which the SRAM 100 is incorporated. These values of RAC1 and RAC2 may be predetermined in some instances or may be determined based upon testing of the memory 101.

Since the transistors T13, T16, and T23, T26 are replicas of the NMOS pass gate transistors PG3, PG4 and PG5, PG6 and formed at the same time and in the same process, and since the transistors T14, T15 and T24, T25 are replicas of the NMOS memory transistors MN3, MN4 and MN5, MN6 and likewise formed at the same time and in the same process, the underdrive transistors T13, T14, T15, T16 and T23, T24, T25, T26 therefore match the memory cells 101 and vary the same with process, voltage, and temperature.

The read assist control signals RAC1 and RAC2 can be digital (as in, either ground or a voltage sufficient to fully turn on transistors T13, T16 and T23, T26) or analog (e.g., either ground or a voltage that turns on the transistor T13, T16 and T23, T26 at least somewhat, this analog voltage being compensated for process, voltage, and temperature variation), thereby permitting the setting and tuning of the total amount of word line underdrive, for example to address specific process corners of concern.

Two tracking columns 110(1) and 110(2) are shown, but as stated, there may be any number of such tracking columns. Through the selection of which tracking columns are on, the amount of word line underdrive may be set or tuned in such embodiments.

As compared to prior designs, the described design provides for word line underdrive that tracks the memory cells properly over process, voltage, and temperature. Due to the simple structure, including the circuit describe above easily fits within the typical pitches utilized for the memory cells. Still further, no complex logic is required in order to drive the devices within the word line underdrive circuit.

Variations of this design are envisioned. For example, it may be desired for there to be a set standard amount of word line underdrive with a selectable optional amount of word line underdrive, or it may be desired for there to be additional word line underdrive that tracks the logic (e.g., the transistors of the word line drivers 105-109).

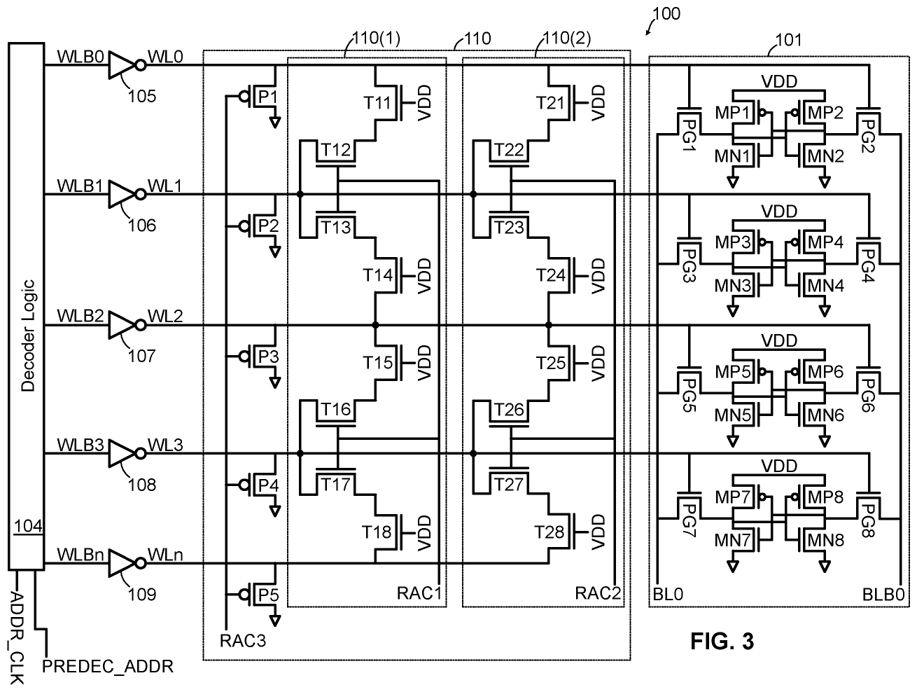

One embodiment allow for this is shown in FIG. 3, which shows that a small PMOS bleeder transistor P1-P5 may be source-drain connected between each word line and ground, with the control signals to the PMOS bleeder transistors being digital or being analog and compensated for process, voltage, and temperature variation. In greater detail, the underdrive circuitry 110 includes: PMOS transistor P1 having its source connected to word line WLO, its drain connected to ground, and its gate connected to receive read assist control signal RAC3; PMOS transistor P2 having its source connected to word line WL1, its drain connected to ground, and its gate connected to receive read assist control signal RAC3; PMOS transistor P3 having its source connected to word line WL2, its drain connected to ground, and its gate connected to receive read assist control signal RAC3; PMOS transistor P4 having its source connected to word line WL3, its drain connected to ground, and its gate connected to receive read assist control signal RAC3; and PMOS transistor P5 having its source connected to word line WLn, its drain connected to ground, and its gate connected to receive read assist control signal RAC3. The bleeder transistors P1-P5 are smaller than each of the underdrive transistors within the tracking columns 110(1) and 110(2). The read assist control signal RAC3 may be, as stated, digital or analog and compensated for process, voltage, and temperature variation. The read assist control signal RAC3 causes the PMOS bleeder transistors P1-P5 to sink current from the activated one of the word lines WL0-WLn. Since the PMOS bleeder transistors P1-P5 are smaller than the transistors within the tracking columns 110(1) and 110(2), their usage to provide for an additional level of word line underdrive does not negatively impact the way the word line underdrive tracks the memory cells 101 over process, voltage, and temperature. In fact, the PMOS bleeder transistors P1-P5 can be formed in the same process as the word line drivers 105-109 (for example, having the same length) to track, the PMOS transistors in the word line drivers 105-109 over process, voltage, and temperature.

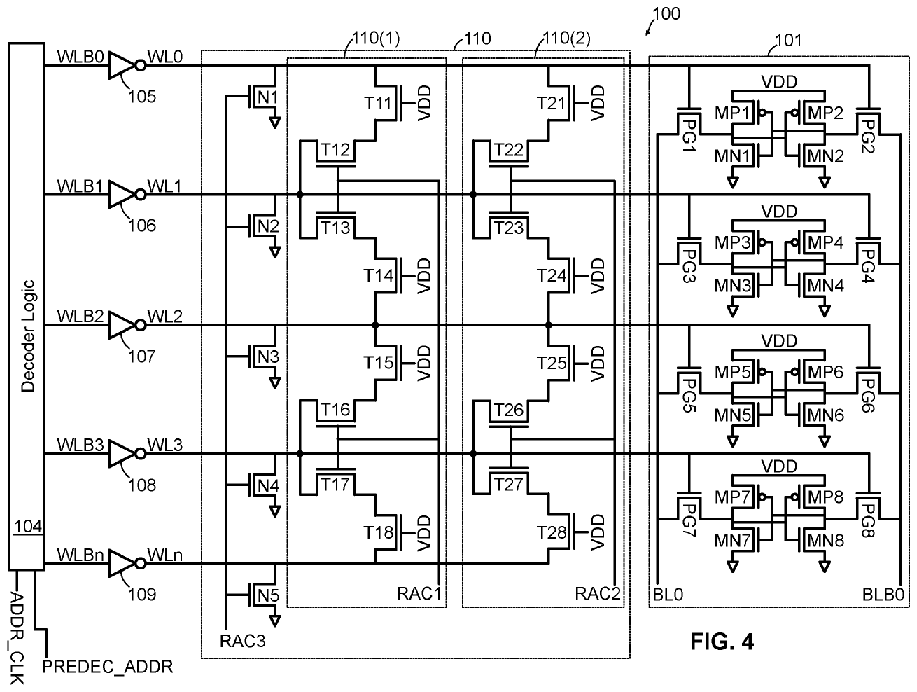

As can be appreciated, a PMOS transistor may be limited in the amount of current it can sink. Given that, in some scenarios, instead of PMOS bleeder transistors, NMOS bleeder transistors N1-N5 may be used, as shown in FIG. 4.

Here, the underdrive circuitry 110 includes: NMOS transistor N1 having its drain connected to word line WLO, its source connected to ground, and its gate connected to receive read assist control signal RAC3; NMOS transistor N2 having its drain connected to word line WL1, its source connected to ground, and its gate connected to receive read assist control signal RAC3; NMOS transistor N3 having its drain connected to word line WL2, its source connected to ground, and its gate connected to receive read assist control signal RAC3; NMOS transistor N4 having its drain connected to word line WL3, its source connected to ground, and its gate connected to receive read assist control signal RAC3; and NMOS transistor N5 having its drain connected to word line WLn, its source connected to ground, and its gate connected to receive read assist control signal RAC3. The functionality is the same as described with reference to FIG. 3. The bleeder transistors N1-N5 are smaller than the underdrive transistors within the tracking columns 110(1) and 110(2) so the varying of the word line underdrive over process, voltage, and temperature still tracks the memory cells 101. Also, the NMOS bleeder transistors N1-N5 can be formed in the same process as the word line drivers 105-109 (for example, having the same length) to track, the NMOS transistors in the word line drivers 105-109 over process, voltage, and temperature.

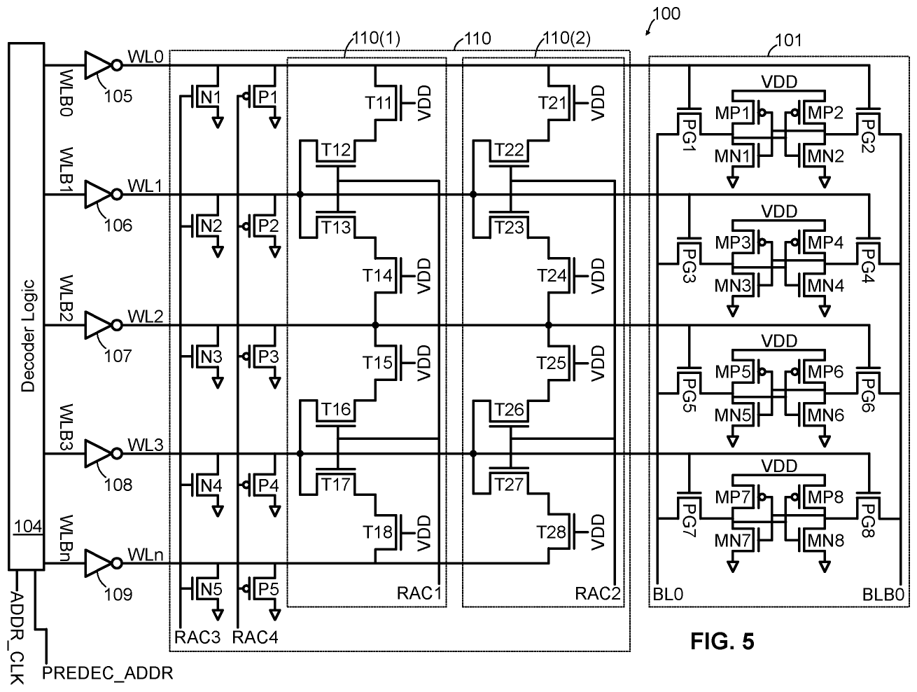

Both PMOS and NMOS bleeder transistors may be used, as shown in FIG. 5.

Here, the underdrive circuitry 110 includes: NMOS transistor N1 having its drain connected to word line WLO, its source connected to ground, and its gate connected to read assist control signal RAC3; NMOS transistor N2 having its drain connected to word line WL1, its source connected to ground, and its gate connected to read assist control signal RAC3; NMOS transistor N3 having its drain connected to word line WL2, its source connected to ground, and its gate connected to read assist control signal RAC3; NMOS transistor N4 having its drain connected to word line WL3, its source connected to ground, and its gate connected to read assist control signal RAC3; and NMOS transistor N5 having its drain connected to word line WLn, its source connected to ground, and its gate connected to read assist control signal RAC3. The read assist control RAC3 may be, as stated, digital or analog and compensated for process, voltage, and temperature variation and cause the NMOS bleeder transistors N1-N5 to sink current from the activated word line WLO-WLn.

The underdrive circuitry 110 also includes: PMOS transistor P1 having its source connected to word line WLO, its drain connected to ground, and its gate connected to read assist control signal RAC4; PMOS transistor P2 having its source connected to word line WL1, its drain connected to ground, and its gate connected to read assist control signal RAC4; PMOS transistor P3 having its source connected to word line WL2, its drain connected to ground, and its gate connected to read assist control signal RAC4; PMOS transistor P4 having its source connected to word line WL3, its drain connected to ground, and its gate connected to read assist control signal RAC4; and PMOS transistor P5 having its source connected to word line WLn, its drain connected to ground, and its gate connected to read assist control signal RAC4.

The bleeder transistors P1-P5 and N1-N5 are smaller than the underdrive transistors within the tracking columns 110(1) and 110(2) so the varying of the word line underdrive over process, voltage, and temperature still tracks the memory cells 101. Additionally, mismatch between transistors in the word line drivers 105-109 and the bleeder transistors P1-P5 and 1-N5 is likewise not of concern due to the smaller size of the bleeder transistors P1-P5 and N1-N5.

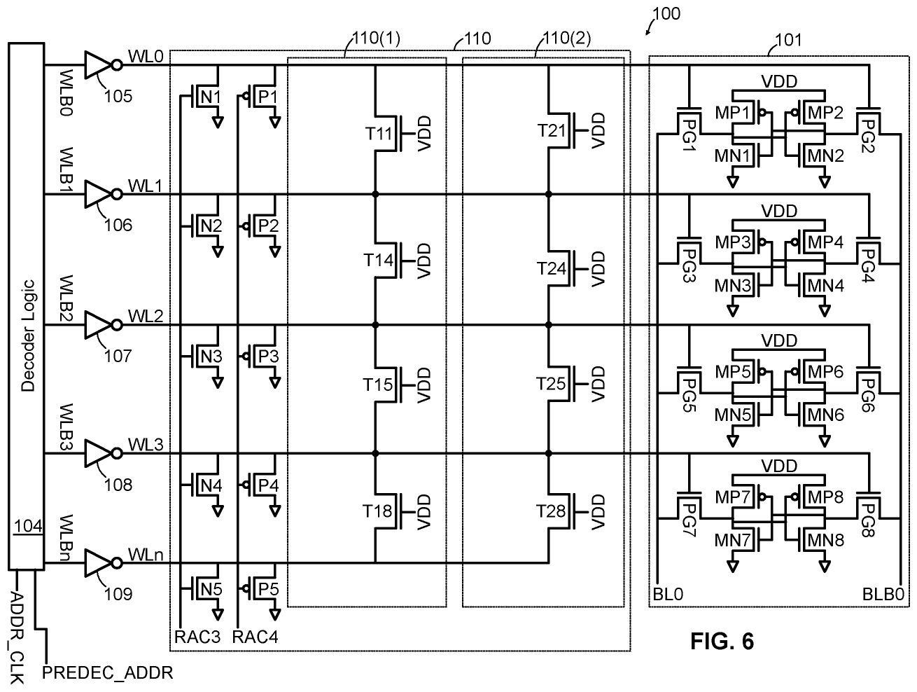

In the above examples, the tracking columns 110(1) and 110(2) include replicas of both the pass gate transistors and the NMOS transistors of the associated memory cells. However, this need not be the case. For example, shown in FIG. 6 is an example with both PMOS and NMOS bleeder transistors but where the tracking columns 110(1) and 110(2) include replicas of the NMOS transistors (e.g., pull down transistors of the cross coupled inverters) of the associated memory cells (or of the pass gate transistors of the associated memory cells, if desired) with replicas of the pass gate transistors not being present.

Thus, in tracking column 110(1), NMOS transistor T11 (a replica of NMOS transistors MN1 and MN2) is connected between word lines WLO and WL1, NMOS transistor T14 (a replica of NMOS transistors MN3 and MN4) is connected between word lines WL1 and WL2, NMOS transistor T15 is connected between word lines WL2 and WL3, and NMOS transistor T18 is connected between word lines WL3 and WLn. Transistors T11 and T14 may share a source/drain region, transistors T14 and T15 may share a source/drain region, and transistors T15 and T18 may share a source/drain region. The gates of transistors T11, T14, T15, and T18 are connected to VDD to maintain those transistors as being on.

Similarly, in tracking column 110(2), NMOS transistor T21 (a replica of NMOS transistors MN1 and MN2) is connected between word lines WLO and WL1, NMOS transistor T24 (a replica of NMOS transistors MN3 and MN4) is connected between word lines WL1 and WL2, NMOS transistor T25 is connected between word lines WL2 and WL3, and NMOS transistor T28 is connected between word lines WL3 and WLn. The gates of transistors T21, T24, T25, and T28 are connected to VDD to maintain those transistors as being on.

Since the transistors in the tracking columns 110(1) and 110(2) have their gates connected to VDD, the amount of word line underdrive is not adjustable and is set through design selection (e.g., how many tracking columns are present, the ratio of the size of the transistors in the tracking columns 110(1) and 110(2) to the size of the transistors in the memory cells 101, etc). However, since the transistors within the tracking columns 110(1) and 110(2) are replicas of the NMOS transistors in the memory cells 101, the word line underdrive in this embodiment will still track the memory cells 101 over process, voltage, and temperature.

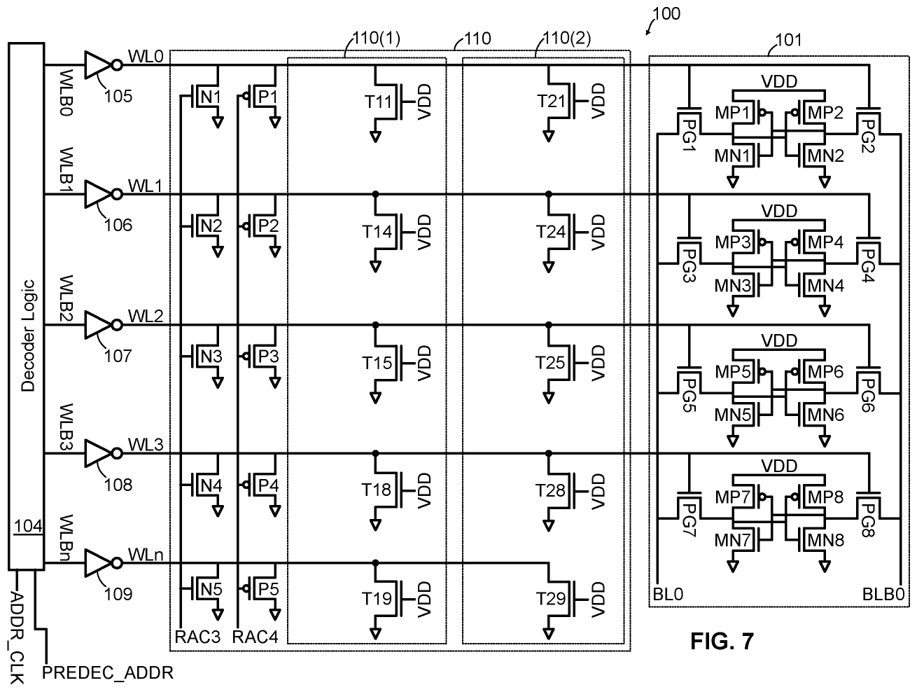

Still referring to FIG. 6, instead of the transistors T11, T14, T15, T18, T21, T24, T25, T28 being connected between respective word lines, they may be connected between respective word lines and ground. This is shown in FIG. 7, in which transistor T11 is connected between word line WLO and ground, transistor T14 is connected between word line WL1 and ground, transistor T15 is connected between word line WL2 and ground, transistor T18 is connected between word line WL3 and ground, and transistor T19 is connected between word line WLn and ground. Likewise, transistor T21 is connected between word line WLO and ground, transistor T24 is connected between word line WL1 and ground, transistor T25 is connected between word line WL2 and ground, transistor T28 is connected between word line WL3 and ground, and transistor T29 is connected between word line WLn and ground. Functionality here is effectively the same as in FIG. 6, with the difference being the current path to ground being directly through the transistors in the tracking columns 110(1) and 110(2) to ground instead of through the transistors and then through unselected word lines to ground.

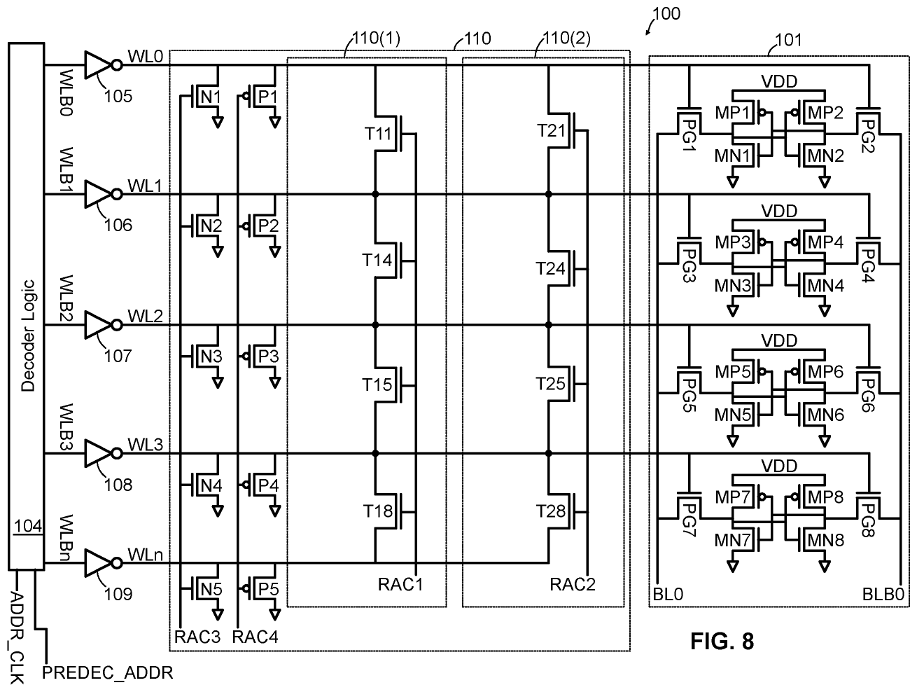

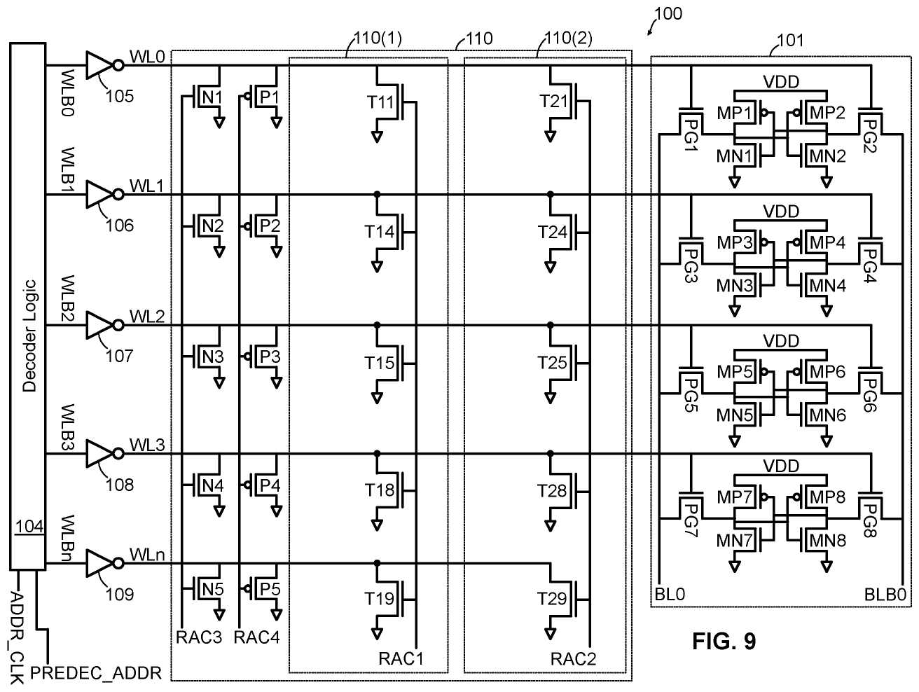

In the above examples of FIGS. 6-7, the transistors T11, T14, T15, T18, and T21, T24, T25, and T28, have their gates connected to VDD, but this need not be the case. As shown in FIGS. 8-9, which otherwise mirror the embodiments of FIG. 6-7, the transistors T11, T14, T15, and T18 may have their gates connected to a digital or analog (and compensated for process, voltage, and temperature variation) read assist control signal RAC1, while transistors T21, T24, T25, and T28 may have their gates connected to a digital or analog (and compensated for process, voltage, and temperature variation) read assist control signal RAC2. Functionality here is effectively the same as FIGS. 5-6, with the level of word line underdrive provided by the tracking columns 110(1) and 110(2) being set by the read assist control signals RAC1 and RAC2.

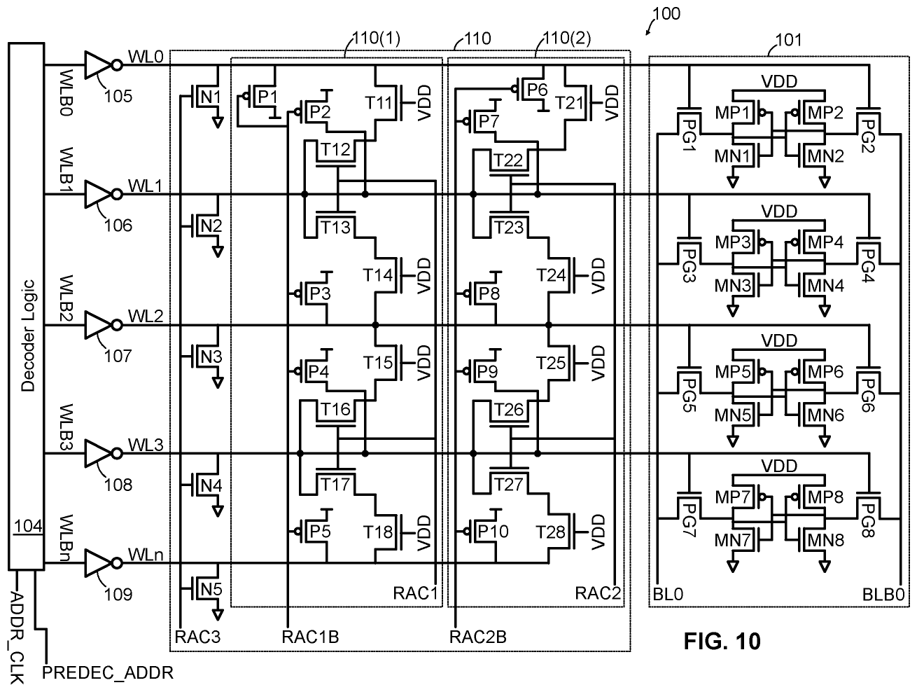

Referring once again to FIG. 4, in some instances, it may be desired for there to be small pull-up transistors in addition to the bleeder transistors. This is shown in FIG. 10, which otherwise mirrors the embodiment of FIG. 4, but in which a small CMOS pull-up transistor is connected between each bit line and VDD, in each tracking column 110(1) and 110(2). For example, in tracking column 110(1), PMOS transistor P1 is connected between VDD and word line WLO, PMOS transistor P2 is connected between VDD and word line WL1, PMOS transistor P3 is connected between VDD and word line WL2, PMOS transistor P4 is connected between VDD and word line WL3, and PMOS transistor P5 is connected between VDD and word line WLn.

In tracking column 110(2), PMOS transistor P6 is connected between VDD and word line WL0, PMOS transistor P7 is connected between VDD and word line WL1, PMOS transistor P8 is connected between VDD and word line WL2, PMOS transistor P9 is connected between VDD and word line WL3, and PMOS transistor P10 is connected between VDD and word line WLn.

The pull-up transistors P1-P10 have their gates connected to an inverse of the first read assist control signal, labeled as RAC1B. The purpose of these pull-up transistors P1-P10 is to provide process, voltage, and temperature compensation to the word line underdriving for the PMOS transistors MP1-MP8 within the individual memory cells 101. These pull-up transistors are therefore replicas of the PMOS transistors within the individual memory cells-P1 is a replica of MP1/MP2, P2 is a replica of MP3/MP4, P3 is a replica of MP5/MP6, P4 is a replica is MP7/MP8, etc.

It is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. An electronic device including a memory, the electronic device comprising:
a plurality of word lines selectively driven by a decoder;
each pair of adjacent word lines having an underdrive circuit coupled therebetween, wherein that underdrive circuit includes first and second transistors source/drain coupled in series with one another between the pair of adjacent word lines,
the first and second transistors being replicas of a pull-down transistor and a pass gate transistor of a bitcell of the memory, and
wherein one of the first and second transistors has a gate driven by a supply voltage and an other of the first and second transistor has a gate driven by a first read assist control signal.

2. The electronic device of claim 1, further comprising, for each word line, a first bleeder transistor source/drain coupled between that word line and ground, with the first bleeder transistor having a gate driven by a second read assist control signal.

3. The electronic device of claim 2, wherein the second read assist control signal is compensated for process, voltage, and temperature variance.

4. The electronic device of claim 2, further comprising, for each word line, a second bleeder transistor source/drain coupled between that word line and ground, the second bleeder transistor having a gate driven by a third read assist control signal; wherein the second bleeder transistor is a MOS transistor of a first conductivity type and the first bleeder transistor is a MOS transistor of a second conductivity type opposite the first conductivity type.

5. The electronic device of claim 1, further comprising, for each word line, a pull-up compensation transistor source-drain coupled between the supply voltage and that word line, with a gate of the pull-up compensation transistor being driven by an inverse of the first read assist control signal.

6. The electronic device of claim 5, further comprising, for each word line, a first bleeder transistor source/drain coupled between that word line and ground, with the first bleeder transistor having a gate driven by a second read assist control signal.

7. An electronic device including a memory, the electronic device comprising:
a plurality of word lines selectively driven by a decoder;
each word line having an underdrive circuit coupled thereto, wherein that underdrive circuit includes a first transistor coupled to that word line, the transistor being a replica of a pull-down transistor or a pass gate transistor of a bitcell of the memory; and
each word line having a first bleeder transistor source/drain coupled between that word line and ground and having a gate driven by a first read assist control signal.

8. The electronic device of claim 7, wherein the first transistor is source/drain coupled between the word line and ground and has a gate driven by a supply voltage.

9. The electronic device of claim 7, wherein the first transistor is source/drain coupled between the word line and ground and has a gate driven by a second read assist control signal.

10. The electronic device of claim 7, wherein the first transistor for each word line is coupled between that word line and an immediately adjacent word line.

11. The electronic device of claim 7, wherein the first transistor for each word line has a gate driven by a supply voltage.

12. The electronic device of claim 7, wherein the first transistor for each word line has a gate driven by a second read assist control signal.

13. The electronic device of claim 7, wherein the first read assist control signal is compensated for process, voltage, and temperature variance.

14. The electronic device of claim 7, wherein the first bleeder transistor is a MOS transistor of a first conductivity type.

15. The electronic device of claim 14, further comprising, for each word line, a second bleeder transistor source/drain coupled between that word line and ground and having a gate driven by a third read assist control signal; the second bleeder transistor is a MOS transistor of a second conductivity type opposite the first conductivity type.

16. An electronic device including a memory, the electronic device comprising:
for each given row within the memory:
decoder logic configured to generate an initial word line signal; and
word line driver circuitry configured to generate a word line drive signal at an intermediate node from the initial word line signal, and to generate a word line signal at a word line node for that given row, from the word line drive signal;
a first adjacent word line node, the first adjacent word line node being associated with a first row immediately adjacent to the given row;
a first replica transistor having a first conduction terminal connected to the first adjacent word line node and a control terminal coupled to a first control signal; and
a second replica transistor having a first conduction terminal connected to a second conduction terminal of the first replica transistor, a second conduction terminal connected to the word line node, and a control terminal coupled to a supply voltage;
wherein the first replica transistor is a replica of pass gate transistors of bitcells in the given row within the memory; and
wherein the second replica transistor is a replica of certain transistors of bitcells in the given row within the memory.

17. The electronic device of claim 16, wherein the first replica transistor is a first replica NMOS transistor having a drain connected to the first adjacent word line node, a source, and a gate coupled to the first control signal; wherein the second replica transistor is a second replica NMOS transistor having a drain connected to the source of the first replica NMOS transistor, a source connected to the word line node, and a gate coupled to the supply voltage; and wherein the second replica transistor is a replica of NMOS transistors of the memory cells of the given row within the memory.

18. The electronic device of claim 16, further comprising a third replica transistor having a first conduction terminal connected to the word line node and a gate coupled to the supply voltage; a fourth replica transistor having a first conduction terminal connected to a second conduction terminal of the third replica transistor, a second conduction terminal coupled to a second adjacent word line node, and a gate coupled to the first control signal; the second adjacent word line node being associated with a second row immediately adjacent to the given row; wherein the third replica transistor is a replica of certain transistors of memory cells associated with the second adjacent word line node; and wherein the fourth replica transistor is a replica of pass gate transistors of the memory cells associated with the second adjacent word line node.

19. The electronic device of claim 18, wherein the third replica transistor is a third replica NMOS transistor having a drain connected to the word line node and a gate coupled to the supply voltage; wherein the fourth replica transistor is a fourth replica NMOS transistor having a drain connected to a source of the third replica transistor, a source connected to the second adjacent word line node, and a gate coupled to the first control signal; and wherein the third replica transistor is a replica of NMOS transistors of the memory cells associated with the second adjacent word line node.

20. The electronic device of claim 16, further comprising, for each given row within the memory:
a first bleeder transistor having a first conduction terminal connected to the word line node, a second conduction terminal connected to ground, and a control terminal coupled to a second control signal.

21. The electronic device of claim 20, wherein the second control signal is compensated for process, voltage, and temperature variation.

22. The electronic device of claim 20, wherein the first bleeder transistor is a bleeder PMOS transistor having a source connected to the word line node, a drain connected to ground, and a gate coupled to the second control signal.

23. The electronic device of claim 20, wherein the first bleeder transistor is a bleeder NMOS transistor having a drain connected to the word line node, a source connected to ground, and a gate coupled to the second control signal.

24. The electronic device of claim 23, further comprising a second bleeder transistor, the second bleeder transistor comprising a bleeder PMOS transistor having a source connected to the word line node, a source connected to ground, and a gate coupled to the second control signal.

25. The electronic device of claim 16, wherein the first control signal is analog and sets a conductivity of the first replica transistor.

26. The electronic device of claim 16, wherein the first control signal is digital and turns the first replica transistor on or off.

27. An electronic device including a memory, the electronic device comprising:
for each given row within the memory:
decoder logic configured to generate a word line drive signal;
word line driver circuitry configured generate a word line signal at a word line node for that given row, from the word line drive signal; and
a replica transistor having a first conduction terminal coupled to the word line node, and a control terminal, wherein the replica transistor is a replica of certain transistors of bitcells of memory cells of the given row within the memory.

28. The electronic device of claim 27, wherein the control terminal of the replica transistor is coupled to a control signal that is compensated for process, voltage, and temperature variation.

29. The electronic device of claim 27, wherein the control terminal of the replica transistor is coupled to a supply voltage.

30. The electronic device of claim 27, wherein the replica transistor has a second conduction terminal coupled to a first adjacent word line node, the first adjacent word line node being associated with a first row immediately adjacent to the given row.

31. The electronic device of claim 27, wherein the replica transistor has a second conduction terminal coupled to ground.

32. The electronic device of claim 27, wherein the replica transistor is a replica NMOS transistor having its drain connected to the word line node, the replica NMOS transistor being a replica of NMOS transistors within the given row within the memory.
